(19) United States
(12) Patent Application Publication
(10) Pub. No.: US 2015/0263246 A1
(43) Pub. Date: Sep. 17, 2015

(54) LIGHT-EMITTING DEVICE AND METHOD OF MANUFACTURING THE SAME, ILLUMINATION LIGHT SOURCE, AND ILLUMINATION DEVICE

(71) Applicant: PANASONIC INTELLECTUAL PROPERTY MANAGEMENT CO., LTD., Osaka (JP)

(72) Inventors: Kohji HIRAMATSU, Osaka (JP); Tomoya IWAHASHI, Osaka (JP); Koji OMURA, Osaka (JP); Ran ZHENG, Osaka (JP)

(73) Assignee: PANASONIC INTELLECTUAL PROPERTY MANAGEMENT CO., LTD., Osaka (JP)

(21) Appl. No.: 14/643,412

(22) Filed: Mar. 10, 2015

(30) Foreign Application Priority Data
Mar. 14, 2014 (JP) 2014-051140

(51) Int. Cl. H01L 33/50; H01L 33/54; H01L 25/075; F21K 99/00

(52) U.S. Cl. CPC H01L 33/507; F21K 9/90; H01L 33/54; H01L 25/0753; H01L 2933/0041; H01L 2933/005

(57) ABSTRACT

A light-emitting device includes a board; and a first light-emitting element array and a second light-emitting element array connected in parallel and each including light-emitting elements mounted on the board and connected in series. The light-emitting elements includes a red LED chip and a blue LED chip. The red LED chip is sealed with a dot of a first sealant, and the blue LED chip is sealed with a dot of a second sealant which is different from the first sealant.

### BACKGROUND

1. Field of the Invention

The present disclosure relates to a light-emitting device and the like. In the light-emitting device, light-emitting elements are mounted on a board and sealed with light-transmissive resin.

2. Description of the Related Art

Semiconductor light-emitting elements, such as light-emitting diodes (LEDs), are high-efficient, space-saving light sources widely used in a variety of illumination devices for illumination or display.

For example, Japanese Unexamined Patent Application Publication No. 2011-146640 (PTL 1) discloses a chip-on-board (COB) light emitting module (light-emitting device) in which LEDs are mounted on a board and sealed with light-transmissive resin.

Application of the light-transmissive resin in manufacture of such light-emitting devices is performed using a method referred to as linear application. In the linear application, a predetermined amount of light-transmissive resin is dispensed from a dispenser moving along an array of LEDs mounted on a board.

### SUMMARY

A light-emitting device according to an aspect of the present disclosure includes: a board; and a first light-emitting element array and a second light-emitting element array connected in parallel and each including a plurality of light-emitting elements mounted on the board and connected in series, the plurality of light-emitting elements in each of the first light-emitting element array and the second light-emitting element array including a first light-emitting element which emits light of a color and a second light-emitting element which emits light of a color different from the color of the light emitted by the first light-emitting element. The first light-emitting element is sealed with a dot of a first sealant, the second light-emitting element is sealed with a dot of a second sealant, and the second sealant is different from the first sealant.

### BRIEF DESCRIPTION OF DRAWINGS

FIG. 1 illustrates an external view of a light-emitting device according to a first embodiment;

FIG. 2 illustrates a plan view of the light-emitting device according to the first embodiment;

FIG. 3 illustrates a cross-sectional view of the light-emitting device taken along the line 3-3 of FIG. 2;

FIG. 4 is a flowchart of a method of manufacturing the light-emitting device according to the first embodiment;

FIG. 5 is a drawing for illustration of a method of sealing LED chips with dots of resin;

FIG. 6 illustrates a plan view of a light-emitting device in which a plurality of LED chips are connected via lines provided on a board;

FIG. 7 illustrates a cross-sectional view of the light-emitting device taken along the line 8-8 of FIG. 6;

FIG. 8 illustrates a plan view of a light-emitting device in which a plurality of blue LED chips are sealed with a single dot of resin;

FIG. 9 illustrates a cross-sectional view of the light-emitting device taken along the line 9-9 of FIG. 8;

FIG. 10 illustrates a schematic configuration of a bulb lamp according to a second embodiment;

FIG. 11 illustrates a cross-sectional view of an illumination device according to a third embodiment; and

FIG. 12 illustrates a perspective external view of the illumination device according to the third embodiment.

### DETAILED DESCRIPTION OF THE PREFERRED EMBODIMENTS

This section starts with a description of a problem with light-emitting devices of the related art, and then a description of embodiments follows. PTL 1 discloses a light-emitting device including LEDs which emit different colors. Application of a different sealant (light-transmissive resin) to LEDs of each type is difficult to perform efficiently by linear application used in the related art.

The following describes light-emitting devices and others according to embodiments with reference to the drawings. Each of the embodiments described below shows a specific example for the present disclosure. The values, shapes, materials, constituent elements, layout and connection of the constituent elements, and others described for the embodiments are given for illustrative purposes only and do not limit the scope of inventive concept disclosed herein. Therefore, among the constituent elements in the following embodiments, constituent elements not recited in any one of the independent claims defining the most generic part of the inventive concept are described as arbitrary structural elements.

The drawings are schematic diagrams, and are therefore not necessarily exact. In the drawings, constituent elements substantially analogous are denoted with the same reference signs. Description of such constituent elements may be omitted or simplified for the second or later appearance of the constituent elements.

### First Embodiment

The following describes a first embodiment.

### [Light-Emitting Device]

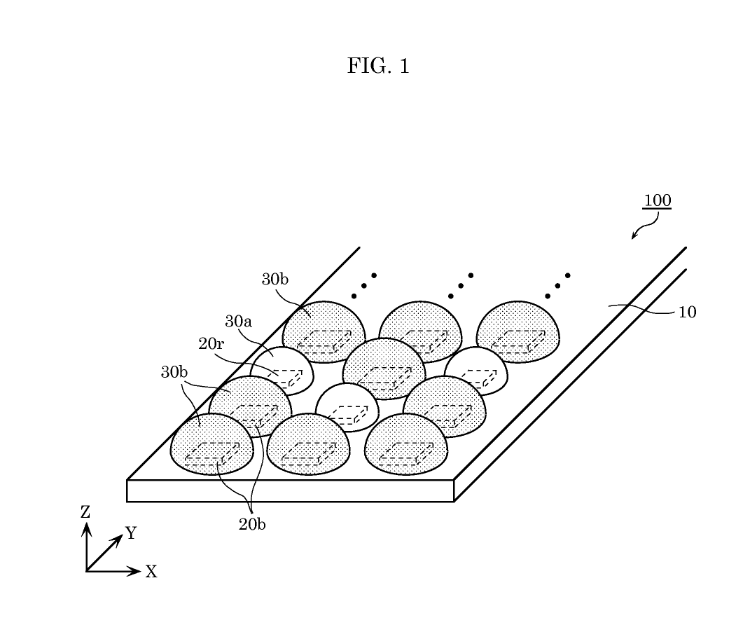

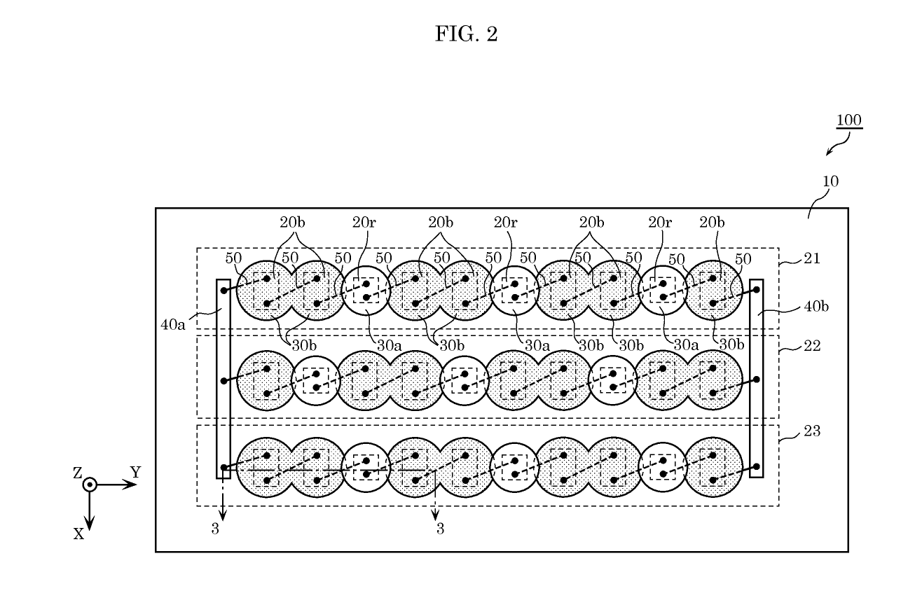

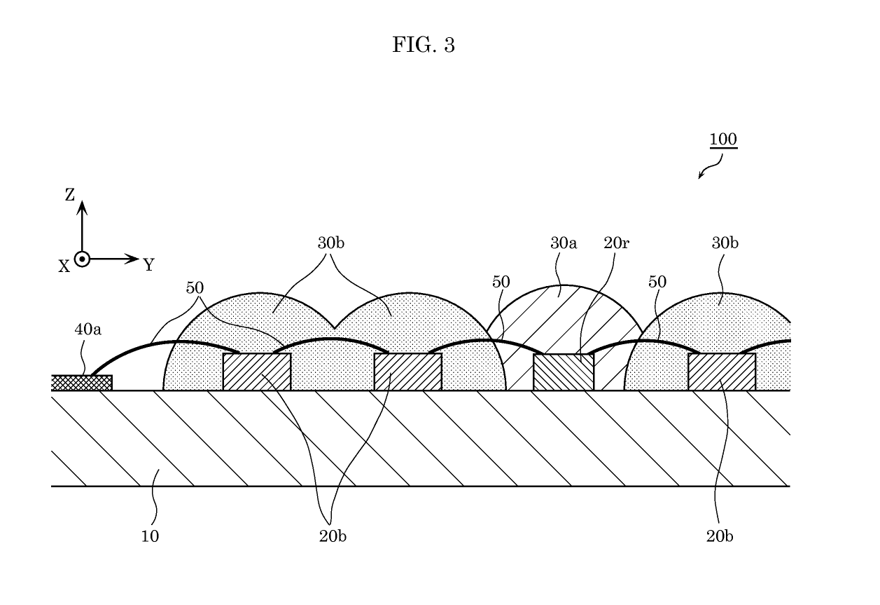

The following describes a configuration of a light-emitting device according to the first embodiment with reference to the drawings. FIG. 1 illustrates a perspective external view of a light-emitting device according to the first embodiment. FIG. 2 illustrates a plan view of light-emitting device 100 according to the first embodiment. FIG. 3 illustrates a cross-sectional view of light-emitting device 100 taken along the line 3-3 of FIG. 2. In FIG. 1, illustration of bonding wires is omitted. FIG. 2 and FIG. 3 illustrate the configuration of the bonding wires differently for convenience of explanation.

As illustrated in FIG. 1 to FIG. 3, light-emitting device 100 includes board 10, first light-emitting element array 21, second light-emitting element array 22, and third light-emitting element array 23. Each of first light-emitting element array 21, second light-emitting element array 22, and third light-emitting element array 23 includes a plurality of LED chips mounted on board 10.

Each of the light-emitting element arrays extends along a Y direction and includes a plurality of red LED chips 20r and a plurality of blue LED chips 20b. As illustrated in FIG. 2, each of the light-emitting element arrays includes three red LED chips 20r and seven blue LED chips 20b. In other words, each of the light-emitting element arrays of light-emitting device 100 includes the same number of red LED chips 20r, and each of the light-emitting element arrays of light-emitting device 100 includes the same number of blue LED chips 20b. Red LED chips 20r are an example of a first light-emitting element, and blue LED chips 20b are an example of a second light-emitting element.

The LED chips included in each of the light-emitting element arrays are aligned in a straight line along the Y direction (that is, along a longer side of board 10 having a rectangular shape). Furthermore, as illustrated in FIG. 2, the LED chips included in the light-emitting element arrays are aligned along an X direction (that is, along a shorter side of board 10 having a rectangular shape). In other words, the plurality of LED chips mounted on board 10 are arranged in a matrix.

As illustrated in FIG. 2 and FIG. 3, in each of the light-emitting element arrays, each of the LED chips has a cathode electrode connected to an anode electrode of a next LED chip with bonding wire 50. In other words, each of the light-emitting element arrays is an array of LED chips (electrically) connected in series.

Furthermore, the anode electrode (or the cathode electrode) of the LED chip at an end of each of the light-emitting element array is connected to line 40a (or line 40b) on board 10 with bonding wire 50. Line 40a and line 40b are supplied with power to cause each of the light-emitting element arrays to emit light. In other words, the light-emitting element arrays included in light-emitting device 100 are (electrically) connected in parallel.

Examples of metal materials for line 40a, line 40b, and bonding wire 50 include gold (Au), silver (Ag), and copper (Cu).

In each of the light-emitting element arrays, red LED chips 20r are sealed with dots of first sealant 30a, and blue LED chips 20b are sealed with dots of second sealant 30b.

First sealant 30a is, for example, a transparent resin, so that red light emitted from red LED chips 20r is output from first sealant 30a without being converted in wavelength (that is, without being converted in color).

Second sealant 30b is, for example, a resin containing a yellow phosphor as a wavelength converting material, so that blue light emitted from blue LED chips 20b is converted into white light by passing through second sealant 30b.

In this manner, light-emitting device 100 outputs red light emitted from red LED chips 20r in addition to white light produced by the combination of blue LED chip 20b and the yellow phosphor, so that light-emitting device 100 has increased color rendering quality.

As described above, light-emitting device 100 in the first embodiment is a what is called chip-on-board (COB) LED module, in which LED chips are directly mounted on board 10. The following describes constituent elements of light-emitting device 100.

### [Board]

Board 10 is a metal-based board or a ceramic board, for example. Optionally, board 10 may be a resin board including resin as a base material.

Examples of the ceramic board include an alumina board made of aluminum oxide (alumina) and an aluminum nitride board made of aluminum nitride. Examples of the metal-based board include a board of an aluminum alloy, a board of an iron alloy, and a board of a copper alloy each having an insulating film on its surface. Examples of the resin board include a glass epoxy board made of glass fibers and epoxy resin.

Board 10 may be a board having high reflectivity (for example, a reflectivity of 90% or higher). When board 10 has such high reflectivity, light emitted from LED chips is reflected by the surface of board 10. Accordingly, light-emitting device 100 has increased light extraction efficiency. Examples of such a board include a white ceramic board including alumina as a base material.

Optionally, board 10 may be a light-transmissive board having a high light transmittance. When board 10 is such a light-transmissive board, light emitted from LED chips passes through board 10 and is also output from a face having no LED chips (rear face). Examples of such a board include a light-transmissive ceramic board made of polycrystalline alumina or alumina nitride, a clear glass board made of glass, a crystal board made of crystal, a sapphire board made of sapphire, and a transparent resin board made of a transparent resin.

Board 10, which is described as being rectangular for the first embodiment, may be otherwise in shape such as a board having a circular shape.

### [LED and Sealant]

The light-emitting elements mounted on board 10 include the plurality of red LED chips 20r and the plurality of blue LED chips 20b.

Red LED chips 20r and blue LED chips 20b are bare chips each emit monochromatic visible light. Examples of semiconductor light-emitting elements used as red LED chips 20r include semiconductor light-emitting elements which are made with an AlGaInP-based material and emit light having a center wavelength (or have a peak wavelength of an emission spectrum) ranging from approximately 630 nanometers to 645 nanometers, inclusive.

Examples of semiconductor light-emitting elements used as blue LED chips 20b include gallium nitride-based semiconductor light-emitting elements which are made with an InGaN-based material and emit light having a center wavelength (or have a peak wavelength of an emission spectrum) ranging from 430 nanometers to 500 nanometers.

As described above, in the first embodiment, red LED chips 20r are sealed with dots of first sealant 30a, and blue LED chips 20b are sealed with dots of second sealant 30b. In other words, red LED chips 20r are sealed with first sealant 30a having a substantially hemispherical (domical) shape, and blue LED chips 20b are sealed with second sealant 30b having a substantially hemispherical shape. As illustrated in FIG. 2 and FIG. 3, the dots of first sealant 30a and second sealant 30b have a substantially semicircular shape in cross-sectional view and a substantially circular shape in plan view.

First sealant 30a does not contain a phosphor and is a light-transmissive resin material such as silicone resin, so that light from red LED chips 20r passes through and is output from first sealant 30a. In other words, first sealant 30a does not function as a wavelength converter (color converter). First sealant 30a is provided to reduce refraction (or reduce total internal reflection of light passing from red LED chips 20r into air) so that the luminous efficiency of red LED chips 20r is increased and red LED chips 20r are protected.

Second sealant 30b is a light-transmissive resin material such as silicone resin and contains yellow phosphor particles. Examples of the light-transmissive resin material include silicone resin. Examples of the yellow phosphor particles include yttrium aluminum garnet (YAG)-based yellow phosphor particles.

In this configuration, part of blue light emitted from blue LED chips 20b is converted in wavelength into yellow light by the yellow phosphor particles contained in second sealant 30b. The center wavelength of the yellow light (or the peak wavelength of the emission spectrum of the yellow phosphor particles) is within a range from 545 nanometers to 570 nanometers, inclusive, for example.

Blue light not absorbed by the yellow phosphor particles and the yellow light converted in wavelength by the yellow phosphor particles diffuse and combine in second sealant 30b to produce white light which is output from second sealing member 30b.

In the first embodiment, the light-transmissive resin material for first sealant 30a and the light-transmissive resin material for second sealant 30b (resin material excluding the phosphor) are substantially the same (both are silicone resin). In other words, second sealant 30b is made of a light-transmissive resin material for first sealant 30a to which a phosphor is added. Such use of the same light-transmissive resin material common for first sealant 30a and second sealant 30b contributes to reduction in material cost.

Optionally, first sealant 30a and second sealant 30b may include a light diffusing agent, such as silica, scattered in each of them. First sealant 30a and second sealant 30b need not be made of a resin material but may be made of an organic material such as fluorine-based resin or an inorganic material such as low-melting-point glass or sol-gel glass.

In the first embodiment, each of the light-emitting element arrays, that is, first light-emitting element array 21, second light-emitting element array 22, and third light-emitting element array 23 includes the same number of red LED chips 20r, and includes the same number of blue LED chips 20b. In other words, light-emitting element arrays 21, 22, and 23 each include the number n of red LED chips 20r (n is an integer greater than or equal to one) and the number m of blue LED chips 20b (m is an integer greater than or equal to one). In this configuration, operating voltage applied across each of light-emitting element arrays 21, 22, and 23 falls within a predetermined range. The ratio of the number of red LED chips 20r mounted on board 10 to the number of blue LED chips 20b, which is described as being 3:7 for the first embodiment, may be otherwise. The ratio of the number of red LED chips 20r to the number of blue LED chips 20b is typically set to n:m=1:k (1≦k≦2) or so. In other words, the number of red LED chips 20r mounted on board 10 is less than or equal to the number of blue LED chips 20b mounted on board 10.

In the first embodiment, each of red LED chips 20r in each of the light-emitting element arrays is disposed non-successively to any other one of red LED chips 20r as illustrated in FIG. 2. In other words, red LED chips 20r are disposed non-successively along the Y direction in FIG. 2. Furthermore, red LED chips 20r in two adjacent ones of the light-emitting element arrays are not aligned. More specifically, red LED chips 20r are disposed non-successively along the X direction in FIG. 2.

In this configuration, red LED chip 20r on board 10 are sparse, so that light from red LED chips 20r mix evenly with white light from second sealant 30b. Accordingly, light-emitting device 100 emits light with higher color uniformity.

Furthermore, as illustrated in FIG. 3, first sealant 30a is above second sealant 30b (or on a positive side of second sealant 30b along the Z axis) at interfaces between first sealant 30a and second sealant 30b. In other words, in light-emitting device 100, first sealant 30a partly covers second sealant 30b. This is because in manufacturing of light-emitting device 100 in the first embodiment, application of second sealing member 30b to seal blue LED chips 20b precedes application of first sealant 30a.

If application of first sealant 30a precedes application of second sealant 30b, sealing of blue LED chips 20b with second sealing member 30b may be incomplete due to presence of first sealant 30a already applied. In such a case, part of blue light emitted from blue LED chips 20b may not even enter second sealant 30b but only enter first sealant 30a to be output from first sealant 30a.

As described above, first sealant 30a does not convert light in wavelength. Therefore, light-emitting device 100 may have color shift of white light (color shift with respect to a designed value) due to leaking blue light output after passing through only first sealant 30a.

Compared to this, if application of second sealing member 30b to seal blue LED chips 20b precedes application of first sealant 30a as in the first embodiment, risk of such color shift due to leaking blue light is reduced.

### [Method of Manufacturing Light-Emitting Device]

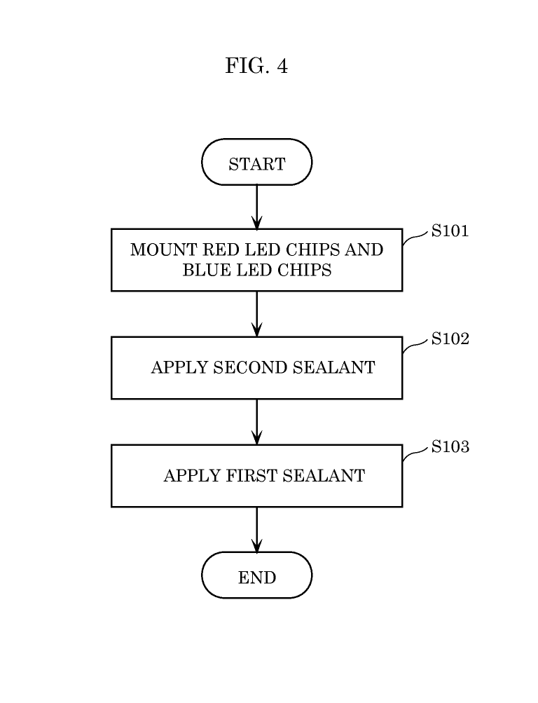

The following describes a method of manufacturing light-emitting device 100 with reference to FIG. 4. FIG. 4 is a flowchart of a method of manufacturing light-emitting device 100.

At the beginning of manufacturing of light-emitting device 100, red LED chips 20r and blue LED chips 20b are mounted on board 10 (S101). Next, each of blue LED chips 20b is sealed with a different dot of second sealant 30b (S102). After sealing of all blue LED chips 20b is completed, each of red LED chips 20r is sealed with a different dot of first sealant 30a (S103).

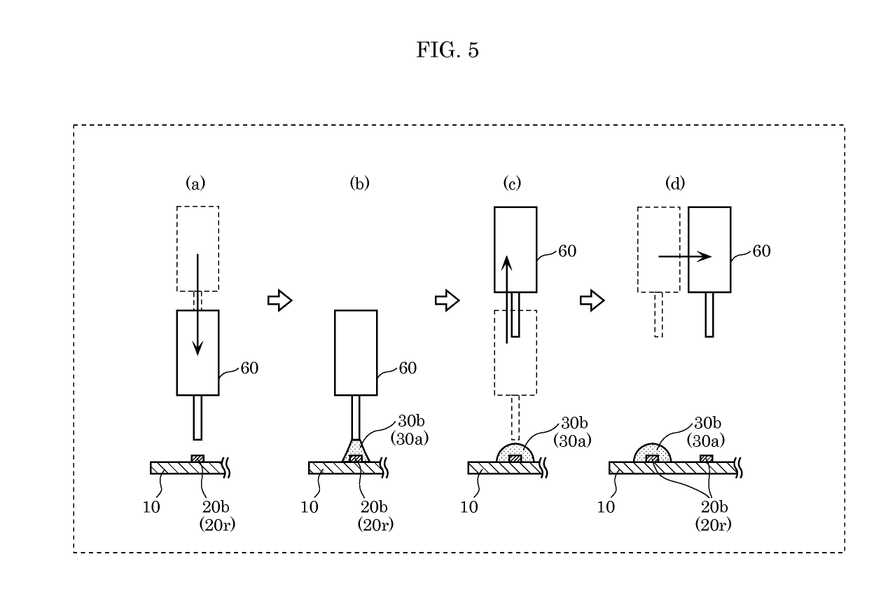

The following describes a method of sealing LED chips with dots of resin in detail with reference to FIG. 5. FIG. 5 is a drawing for illustration of a method of sealing LED chips with dots of resin. The following describes application of second sealant 30b to blue LED chips 20b using a dispenser 60 as an example. Application of first sealant 30a to red LED chips 20r is performed in the same manner.

First, as illustrated in (a) in FIG. 5, a nozzle tip of dispenser 60 is positioned vertically above (a substantially central region of a light emitting surface of) blue LED chip 20b mounted on board 10.

Next, as illustrated in (b) in FIG. 5, second sealant 30b is applied onto blue LED chip 20b from dispenser 60 positioned at a fixed position. Second sealant 30b radially flows outward from where second sealant 30b has landed and forms into a substantially hemispherical shape.

After application of second sealant 30b to one of blue LED chips 20b is completed, dispenser 60 is lifted as illustrated in (c) in FIG. 5. Next, as illustrated in (d) in FIG. 5, dispenser 60 is shifted to above another one of blue LED chips 20b, and then second sealant 30b is applied onto the other one of blue LED chips 20b in the same manner.

In this manner, LED chips are sealed with dots of resin by applying a sealant dispensed from a nozzle tip of dispenser 60 to the individual LED chips. While dispensing the sealant to each of the LED chips, the nozzle tip is at a fixed position with respect to the LED chip. This differentiates the method from linear application, in which a sealant is applied by moving the nozzle tip of dispenser 60 dispensing the sealant along a light-emitting element array.

Furthermore, in each of the light-emitting element arrays, the dots of resin sealing two adjacent blue LED chips 20b combine having a constriction between the two adjacent blue LED chips 20b as illustrated in FIG. 2 and FIG. 3. The constriction is usually recognizable both in cross-sectional view and in plan view.

The amount of second sealant 30b applied to each of blue LED chips 20b on board 10 is substantially the same, so that the height of blue LED chips 20b above the mounting surface of board 10 is substantially the same.

Sealant may be applied to the plurality of LED chips in any order. The following describes an exemplary order of application in the first embodiment.

First, application of second sealant 30b from dispenser 60 is performed in order of first light-emitting element array 21, second light-emitting element array, and third light-emitting element array.

More specifically, first, dispenser 60 applies second sealant 30b to blue LED chips 20b in first light-emitting element array 21 in sequence from an endmost one of blue LED chips 20b along the Y direction. After completing application of second sealant 30b in first light-emitting element array 21, dispenser 60 applies second sealant 30b to blue LED chips 20b in second light-emitting element array 22, which lies next to first light-emitting element array 21, in sequence from an endmost one of blue LED chips 20b along the Y direction. Similarly, after completing application of second sealant 30b in second light-emitting element array 22, dispenser 60 applies second sealant 30b in third light-emitting element array 23.

After completing application to all blue LED chips 20b on board 10, application of first sealant 30a from dispenser 60 is performed in order of first light-emitting element array 21, second light-emitting element array, and third light-emitting element array.

More specifically, first, dispenser 60 applies first sealant 30a to red LED chips 20r in first light-emitting element array 21 in sequence from an endmost one of red LED chips 20a along the Y direction. After completing application of first sealant 30a in first light-emitting element array 21, dispenser 60 applies first sealant 30a to red LED chips 20r in second light-emitting element array 22 in sequence from an endmost one of red LED chips 20r along the Y direction. Similarly, after completing application of first sealant 30a in second light-emitting element array 22, dispenser 60 applies first sealant 30a in third light-emitting element array 23.

Optionally, first sealant 30a may be applied by dripping first sealant 30a from the tip of dispenser 60 onto red LED chips 20a. Similarly, second sealant 30b may be applied by dripping second sealant 30a from the tip of dispenser 60 onto blue LED chips 20b. By using this method, red LED chips 20a and blue LED chips 20b are sealed with dots of first sealant 30a and dots of second sealant 30b, respectively.

In the first embodiment, application of second sealant 30b may either precede application of first sealant 30a to reduce risk of color shift due to leaking blue light as described above (see FIG. 4) or follow application of first sealant 30a.

In the first embodiment, application of first sealant 30a and application of second sealant 30b are performed using the single dispenser 60 as an example. A separate dispenser may be used for each of the sealant 30a and the sealant 30b. In other words, the dispenser for application of first sealant 30a and the dispenser for application of second sealant 30b may be different dispensers.

Such a way of application of sealant in dots using dispenser 60 requires a small amount of sealant compared to the conventional method in which sealant is linearly applied along a light-emitting element array, and is therefore advantageous in terms of material cost.

### [Advantageous Effects Etc.]

As described above, light-emitting device 100 includes at least board 10, first light-emitting element array 21, and second light-emitting element array 22. Each of first light-emitting element array 21 and second light-emitting element array 22 includes LED chips mounted on board 10 and connected in series. The LED chips in either light-emitting element array include red LED chips 20r which emit light of a color and blue LED chips 20b which emit light of a color different from the color of light emitted by LED chips 20r. First light-emitting element array 21 and second light-emitting element array 22 are connected in parallel.

As described above, in light-emitting device 100, red LED chips 20r are sealed with dots of first sealant 30a, and blue LED chips 20b are sealed with dots of second sealant 30b. First sealant 30a and second sealant 30b are different from each other.

Such a way of application of sealant in dots is efficient and of a high degree of freedom even when, for example, red LED chips 20r and blue LED chips 20b are arranged sparsely. Application of sealant in (domical) dots is advantageous particularly to a configuration in which any pair of red LED chip 20r are disposed non-successively as in light-emitting device 100.

### [First Variation]

In the above-described first embodiment, the LED chips including red LED chips 20r and blue LED chips 20b mounted on board 10 are connected in series, chip to chip, by bonding wires 50. Optionally, the LED chips may be connected via a line (metal film) provided on board 10.

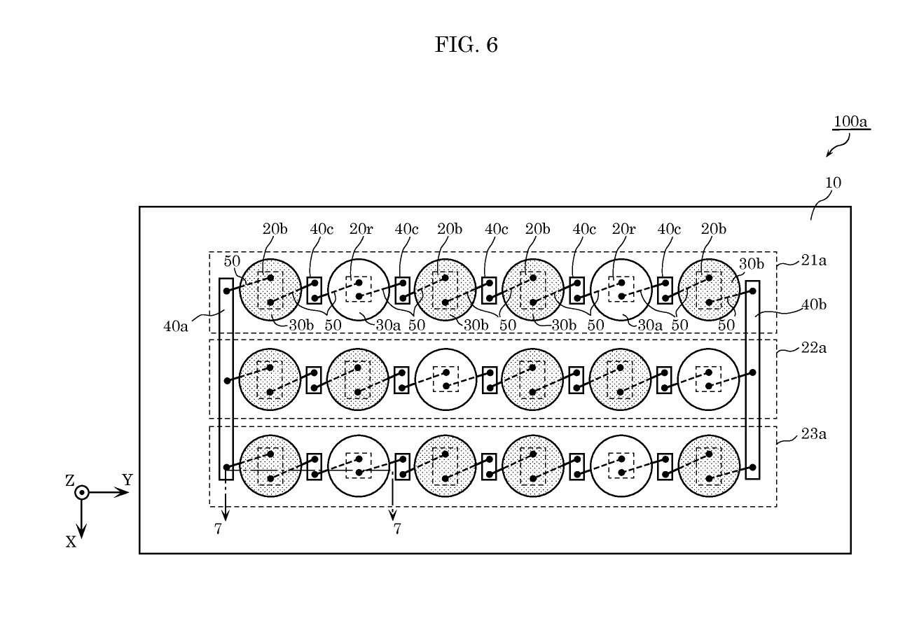

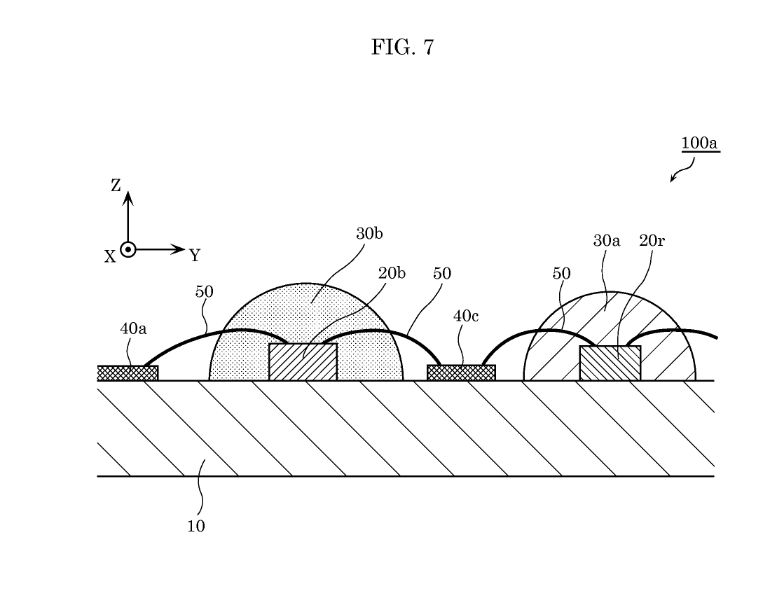

The following describes a first variation of light-emitting device 100 according to the first embodiment. FIG. 6 illustrates a plan view of a light-emitting device in which a plurality of LED chips are connected via lines provided on board 10. FIG. 7 illustrates a cross-sectional view of the light-emitting device taken along the line 7-7 of FIG. 6. Hereinafter, description of constituent elements substantially analogous to the constituent elements of light-emitting device 100 is omitted.

As illustrated in FIG. 6 and FIG. 7, light-emitting device 100a includes first light-emitting element array 21a, second light-emitting element array 22a, and third light-emitting element array 23a.

In each of the light-emitting element arrays in light-emitting device 100a, bonding wire 50 connects the cathode electrode of an LED chip (first LED chip) to line (bonding pad) 40c provided between first LED chip and an LED chip next to the first LED chip (second LED chip). Line 40c and the anode electrode of the second LED chip are connected with bonding wire 50. In other words, each of the light-emitting element arrays in light-emitting device 100a is an array of LED chips (electrically) connected in series via lines provided on board 10.

Furthermore, the LED chip at either end of each of the light-emitting element arrays is connected to line 40a (or line 40b) on board 10 with bonding wire 50 as illustrated in FIG. 6 and FIG. 7. Line 40a and line 40b are supplied with power to cause each of the light-emitting element arrays to emit light.

In each of the light-emitting element arrays, red LED chips 20r are sealed with dots of first sealant 30a, and blue LED chips 20b are sealed with dots of second sealant 30b.

Even in the case of such light-emitting device 100a, such a way of application or sealant in dots is efficient and of a high degree of freedom even when, for example, red LED chips 20r and blue LED chips 20b are arranged sparsely.

### [Second Variation]

In the above-described first embodiment, each of the LED chips (red LED chips 20r and blue LED chips 20b) included in each light-emitting element array are sealed (one by one) with a different dot of resin. Optionally, two or more LED chips in each light-emitting element array may be sealed with a single dot of resin.

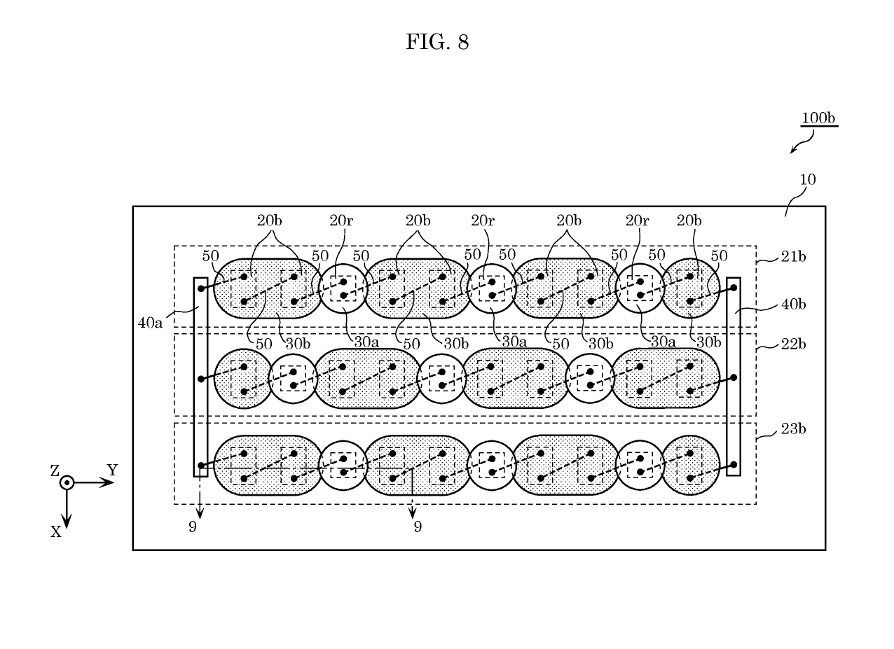

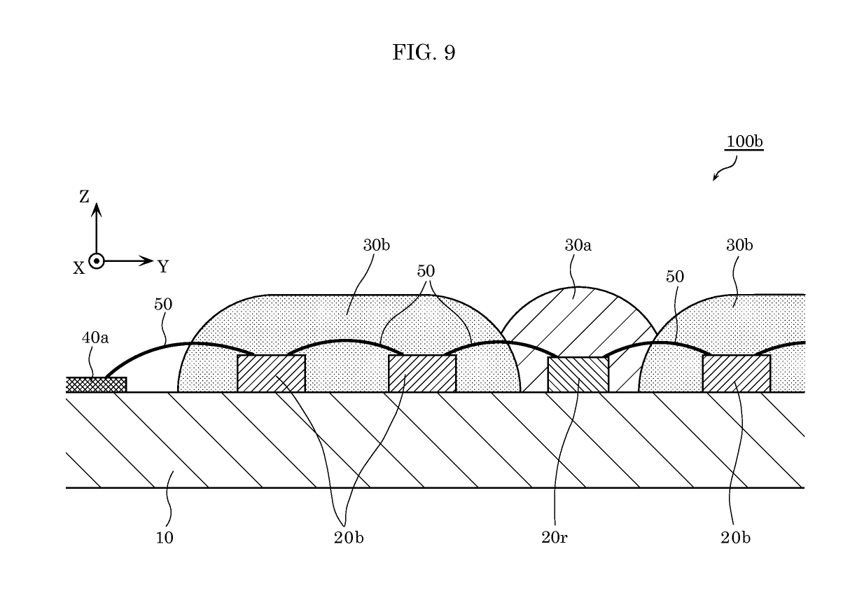

The following describes a second variation of light-emitting device 100 according to the first embodiment. FIG. 8 illustrates a plan view of a light-emitting device in which a plurality of blue LED chips 20b are sealed with a single dot of resin. FIG. 9 illustrates a cross-sectional view of light-emitting device 100 taken along the line 9-9 of FIG. 8. Hereinafter, description of constituent elements substantially analogous to the constituent elements of light-emitting device 100 is omitted.

As illustrated in FIG. 8 and FIG. 9, light-emitting device 100b includes first light-emitting element array 21b, second light-emitting element array 22b, and third light-emitting element array 23b.

In each of the light-emitting element arrays, each of red LED chips 20r is sealed with a different dot of first sealant 30a. In contrast, blue LED chips 20b are sealed basically in pairs with respective dots of second sealant 30b (S102). It is noted that blue LED chips 20b include the one individually sealed with a single dot of resin. In this case, each dot of second sealant 30b is substantially oval (or formed substantially in a shape of an oval racetrack) in plan view as illustrated in FIG. 8.

When blue LED chips 20b are to be sealed in pairs with respective dots of resin, the application amount of second sealant 30b from dispenser 60 and the position of the nozzle tip of dispenser 60 are adjusted as appropriate.

Even in the case of such light-emitting device 100b, such a way of application of sealant in dots is efficient and of a high degree of freedom.

For example, when the ratio of the number of red LED chips 20r to the number of blue LED chips 20b in a light-emitting element array is 1:2, the light-emitting element array probably includes pairs of blue LED chips 20b arranged successively.

In such a case, red LED chips 20r are sealed one by one, and blue LED chips 20b are sealed two by two, so that efficient application of sealant is achieved. In other words, sealing a set of LED chips arranged successively with a single dot of resin according to the ratio of LED chips of different types saves time to be taken to apply a sealant.

### Second Embodiment

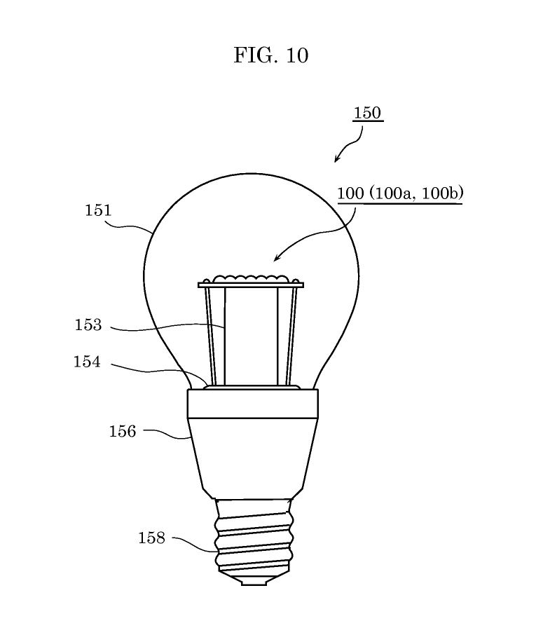

The following describes a configuration of bulb lamp 150 according to the second embodiment with reference to FIG. 10.

FIG. 10 illustrates a schematic configuration of bulb lamp 150 according to the second embodiment.

Bulb lamp 150 illustrated in FIG. 10 is an example of an illumination light source and includes light-emitting device 100 according to the first embodiment.

Bulb lamp 150 includes bulb 151, light-emitting device 100, chassis 156, and cap 158. Bulb 151 is light-transmissive. Light-emitting device 100 is a light source. Chassis 156 contains a driver circuit through which power is supplied to light-emitting device 100. Cap 158 receives power from outside bulb lamp 150.

Cap 158 receives alternating-current (AC) power, and the driver circuit converts the AC power into direct-current (DC) power and supplies the DC power to light-emitting device 100. When the power supplied through cap 158 is DC power, the driver circuit need not be capable of AC-to-DC conversion.

In the second embodiment, light-emitting device 100 is supported by stem 153 so that light-emitting device 100 is positioned at the central part of bulb 151. Stem 153 is a metal rod extending from near the opening of bulb 151 inward bulb 151.

More specifically, stem 153 is connected to support board 154 disposed near the opening of bulb 151.

Optionally, light-emitting device 100 may be supported directly by support board 154 instead of stem 153. In other words, light-emitting device 100 may be mounted on a face of support board 154 facing the interior of bulb 151.

Bulb 151 is a light-transmissive cover which transmits light from light-emitting device 100 to outside. Bulb 151 in the second embodiment is made of a material transparent to light from light-emitting device 100. Examples of such bulb 151 include a glass bulb (clear bulb) of silica glass transparent to visible light.

In this case, light-emitting device 100 contained in bulb 151 is visible from outside bulb 151.

Bulb 151 need not be transparent to visible light and may diffuse light. For example, bulb 151 may have a white light-diffusing film which is formed by applying white pigment or resin including alight diffuser such as silica or calcium carbonate to the interior or exterior of bulb 151. The material for bulb 151 is not limited to glass. Resin may be used as a material for bulb 151. Examples of the resin include synthetic resin such as acrylic (polymethylmethacrylate or PMMA) and polycarbonate (PC).

The shape of bulb 151 is not limited to a particular shape. For example, when light-emitting device 100 is supported directly by support board 154 (that is, when light-emitting device 100 does not include stem 153), bulb 151 may be hemispherical.

Including light-emitting device 100 according to the first embodiment, bulb lamp 150 has increased color rendering quality and is capable of being manufactured with increased productivity.

Bulb lamp 150 is an example of an illumination light source including light-emitting device 100 according to the first embodiment for the second embodiment. An illumination light source including light-emitting device 100 may be also implemented as a straight tube lamp.

Furthermore, light-emitting device 100a or light-emitting device 100b described for the first embodiment may be included in bulb lamp 150 (illumination light source) instead of light-emitting device 100.

### Third Embodiment

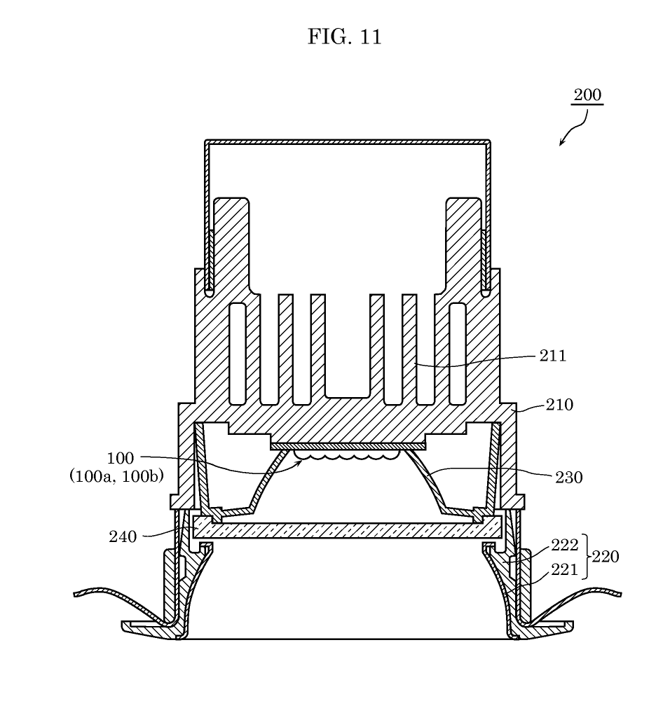

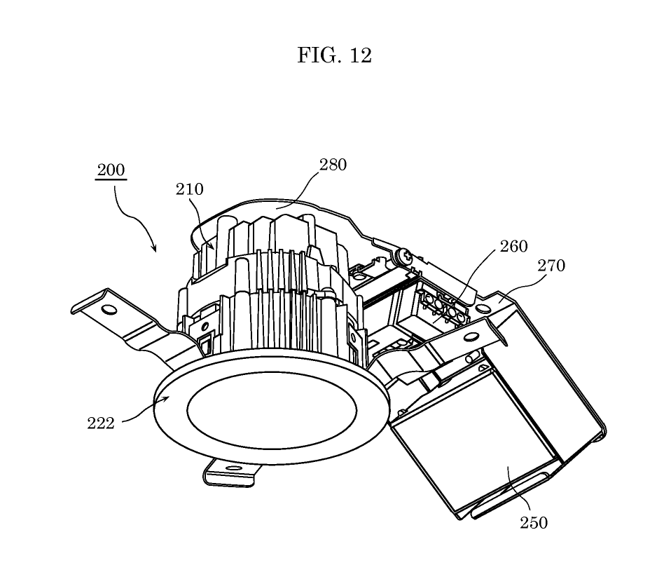

The following describes a configuration of illumination device 200 according to the third embodiment with reference to FIG. 11 and FIG. 12.

FIG. 11 illustrates a cross-sectional view of illumination device 200 according to a third embodiment;

FIG. 12 illustrates a perspective external view of illumination device 200 according to the third embodiment.

As illustrated in FIG. 11 and FIG. 12, illumination device 200 according to the third embodiment is a recessed illumination device. For example, illumination device 200 is a downlight embedded in a ceiling of a house and emits light downward (toward a floor or a wall).

Illumination device 200 includes light-emitting device 100 according to the first embodiment. Illumination device 200 further includes a device body, reflective plate 230, and light-transmissive panel 240. The device body includes base unit 210 and frame unit 220 coupled together and substantially has a shape of a bottomed cylinder. Reflective plate 230 and light-transmissive panel 240 are installed on the device body.

Base unit 210 is a base on which light-emitting device 100 is installed and is a heatsink to dissipate heat generated by light-emitting device 100. Base unit 210 is made of a metal material and is substantially columnar in shape. Base unit 210 in the third embodiment is formed of die-cast aluminum.

The upper part (the portion in the ceiling) of base unit 210 includes radiation fins 211 extending upward and arranged parallel to one another at fixed intervals. These radiation fins 211 allow for efficient dissipation of heat generated by light-emitting device 100.

Frame unit 220 includes cone part 221 and frame body 222 to which cone part 221 is coupled. Cone part 221 is substantially cylindrical and has a reflective interior surface. Cone part 221 is formed of a metal material, and is made by raising or stamping an aluminum alloy, for example. Frame body 222 is formed of a hard resin or a metal material. Frame body 222 is coupled to base unit 210, so that frame unit 220 is fixed.

Reflective plate 230 is a hollow-conical (or funnel-shaped) reflector of internal reflection. Reflective plate 230 is formed of, for example, a metal material such as aluminum. Optionally, reflective plate 230 may be formed of a hard white resin material instead of a metal material.

Light-transmissive panel 240 is a light-transmissive member which diffuses and transmits light. Light-transmissive panel 240 is a planar plate disposed between reflective plate 230 and frame body 220, and is coupled to reflective plate 230. Light-transmissive panel 240 is made of a transparent resin material, such as acrylic or polycarbonate, formed into a disc.

Illumination device 200 need not include light-transmissive panel 240. When illumination device 200 does not include light-transmissive panel 240, light emitted from illumination device 200 has an increased luminous flux.

Furthermore, illumination device 200 is connected with lighting power supply 250 and terminal block 260. Lighting power supply 250 supplies lighting power to light-emitting device 100 as illustrated in FIG. 12. Terminal block 260 relays alternating-current power from a commercial power source to lighting power supply 250.

Lighting power supply 250 and terminal block 260 are fastened to mounting board 270 which is a part separate from the device body. Mounting board 270 is a rectangular metal board in flexion. Lighting power supply 250 is fastened on a lower face of mounting board 270 at one end part in the longitudinal direction of mounting board 270, and terminal block 260 is fastened on the lower face at the other end part. Mounting board 270 is connected to top board 280 fastened to the upper part of base unit 210 of the device body.

Including light-emitting device 100 according to the first embodiment, illumination device 200 has increased color rendering quality and is capable of being manufactured with increased productivity.

The above-described downlight is an example of illumination device 200 including light-emitting device 100 according to the first embodiment for the third embodiment. Such an illumination device including light-emitting device 100 may be implemented as an illumination device of a different type, such as a spotlight or a ceiling light.

Furthermore, light-emitting device 100a or light-emitting device 100b described for the first embodiment may be included in illumination device 200 instead of light-emitting device 100.

### OTHER EMBODIMENTS

The present invention is not limited to the above-described first to third embodiments on the basis of which the light-emitting device, the method of manufacturing the light-emitting device, the illumination light source, and the illumination device as disclosed above.

For example, the light-emitting device according to the above-described embodiments produces white light using blue LED chips 20b and a yellow phosphor in combination. In the present invention, white light may be produced otherwise than this combination.

For example, phosphor containing resin containing a red phosphor and a green phosphor may be used in combination with blue LED chips 20b. Optionally, ultraviolet LED chips may be used in combination with blue phosphor particles, green phosphor particles, and red phosphor particles. The ultraviolet LED chips emit ultraviolet light, which is shorter in wavelength than light emitted by blue LED chips 20b. The blue phosphor particles, red phosphor particles, and greed phosphor particles are excited mainly by the ultraviolet light to emit blue light, green light, and red light.

The present invention is not limited to the light-emitting element arrays according to the above-described embodiments, in which the LED chips are arranged linearly. For example, the light-emitting element array may be an array of LED chips arranged along a circular arc.

The number of the light-emitting element arrays and the number of LED chips included in each of the light-emitting element arrays are not limited in particular. For example, each of the light-emitting element arrays may include, as a third light-emitting element, an LED chip which emits light of a color different from the color of light emitted from red LED chips 20r or blue LED chips 20b.

The LED chips are an example of light-emitting elements used in the light-emitting device in the above-described embodiments. Instead, solid-state light-emitting elements of other types, including semiconductor light-emitting element such as semiconductor lasers, or electro luminescence (EL) devices such as organic EL devices and inorganic EL devices may be used.

Embodiments resulting from various modifications of the above-described embodiments as well as embodiments resulting from any combinations of constituent elements of the different embodiments that may be conceived by those skilled in the art are also intended to be included within the scope of the present invention as long as they do not depart from the essence of the present disclosure.

What is claimed is:

1. A light-emitting device comprising:
a board; and
a first light-emitting element array and a second light-emitting element array connected in parallel and each including a plurality of light-emitting elements mounted on the board and connected in series, the plurality of light-emitting elements in each of the first light-emitting element array and the second light-emitting element array including a first light-emitting element which emits light of a color and a second light-emitting element which emits light of a color different from the color of the light emitted by the first light-emitting element,
wherein the first light-emitting element is sealed with a dot of a first sealant,
the second light-emitting element is sealed with a dot of a second sealant, and
the second sealant is different from the first sealant.

2. The light-emitting device according to claim 1,
wherein each of a plurality of the first light-emitting elements is sealed with a different one of a plurality of the dots of the first sealant, and
each of a plurality of the second light-emitting elements is sealed with a different one of a plurality of the dots of the second sealant.

3. The light-emitting device according to claim 1,
wherein the light emitted by the first light-emitting element is red light, and
the light emitted by the second light-emitting element is blue light.

4. The light-emitting device according to claim 3,
wherein the first light-emitting element is a red light-emitting diode (LED) having an emission spectrum with a peak wavelength ranging from 630 nanometers to 645 nanometers, inclusive, and
the second light-emitting element is a blue LED having an emission spectrum with a peak wavelength ranging from 430 nanometers to 500 nanometers, inclusive.

5. The light-emitting device according to claim 1,
wherein the first sealant is a light-transmissive resin material containing no phosphor, and
the second sealant is a light-transmissive resin material containing a phosphor.

6. The light-emitting device according to claim 5,
wherein the second sealant is the light-transmissive resin material for the first sealant to which a phosphor is added.

7. The light-emitting device according to claim 6,
wherein the phosphor contained in the second sealant has an emission spectrum with a peak wavelength ranging from 545 nanometers to 570 nanometers, inclusive.

8. The light-emitting device according to claim 1,
wherein each of the first light-emitting element array and the second light-emitting element array includes a plurality of the first light-emitting elements, and
in each of the first light-emitting element array and the second light-emitting element array, each of the plurality of the first light-emitting elements is disposed non-successively to any other one of the plurality of the first light-emitting elements.

9. A method of manufacturing the light-emitting device according to claim 1, the method comprising:
sealing the first light-emitting element with a dot of the first sealant by applying the first sealant from a fixed position with respect to the first light-emitting element; and
sealing the second light-emitting element with a dot of the second sealant by applying the second sealant from a fixed position with respect to the second light-emitting element.

10. The method according to claim 9,
wherein the first sealant is a light-transmissive resin material including no phosphor,
the second sealant is a light-transmissive resin material including a phosphor, and
the sealing of the first light-emitting element is performed after the sealing of the second light-emitting element.

11. An illumination light source comprising
the light-emitting device according to claim 1.

12. An illumination device comprising
the light-emitting device according to claim 1.
